(19) United States
(12) Patent Application Publication
(10) Pub. No.: US 2008/0267074 A1
(43) Pub. Date: Oct. 30, 2008

(54) METHOD OF SETING QoS PACKET FLOW AND HANDLING QoS PACKET IN PACKET SWITCHING SYSTEM

(75) Inventors: Jee Yon Choi, Daejeon (KR); Yoo-Kyoung Lee, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics & Telecommunications Research Institute, Daejeon (KR)

(21) Appl. No.: 12/023,767

(22) Filed: Jan. 31, 2008

(30) Foreign Application Priority Data
Apr. 24, 2007 (KR) 10-2007-0039955

(51) Int. Cl. G01R 31/08

(52) U.S. Cl. 370/238

(57) ABSTRACT

Provided is a method of setting a QoS packet flow and processing a QoS packet for providing a QoS service. In the method of setting a QoS packet flow in the packet switching system, whether there are VOQs that are not pre-allocated is determined in response to a QoS packet flow setting request. If there are no VOQs that are not pre-allocated, it is determined whether there are VOQs that have not been used for a predetermined period. If there are VOQs that have not been used for the predetermined period, one of the VOQs is selected. Thereafter, an inactive state of a flow using the selected VOQ is indicated and QoS parameters set for the flow are released. Therefore, metro Ethernet services such as E-LINE and E-LAN can be provided in an Ethernet network and custom QoS services such as Diff Serv and ACL can be provided in an IP network. Also, limited resources can be efficiently used and thus costs can be reduced.

### CROSS-REFERENCE TO RELATED PATENT APPLICATION

This application claims the benefit of Korean Patent Application No. 10-2007-0039955, filed on Apr. 24, 2007, in the Korean Intellectual Property Office, the disclosure of which is incorporated herein in its entirety by reference.

### BACKGROUND OF THE INVENTION

1. Field of the Invention

The present invention relates to a method of setting a Quality of Service (QoS) packet flow and processing a QoS packet in a packet switching system for providing a custom QoS service, and more particularly, to a method of providing a custom QoS service for more flows using a limited number of queues.

This work was supported by the IT R&D program of MIC/IITA [2005-S-102-02, Carrier Class Ethernet Technology]

2. Description of the Related Art

A conventional packet switching system includes a plurality of input interfaces, a plurality of output interfaces, and a switch fabric. The output interface determines, based on header information of a packet input into the system, an output port through which the packet is to be output, and stores the packet in a Virtual Output Queue (VOQ) determined according to the output port.

The output interface provides the input interface with a scheduling signal informing that a scheduler is permitted or forbidden to transmit a packet, depending on the states of an output packet buffer.

The input interface outputs a packet from a VOQ according to the scheduling signal. The packet from the input interface is switched by the switch fabric and is output through the output interface of the output port to the outside of the conventional packet switching system.

FIG. 1 is a block diagram of a conventional packet switching system for providing a Quality of Service (QoS) service.

Referring to FIG. 1, the conventional packet switching system includes a plurality of input interfaces, a QoS controller, a switch fabric, and a plurality of output interfaces.

The operation of the conventional packet switching system, for providing a custom QoS service, can be divided into a packet handling operation and a flow setting operation. The packet handling operation is performed as follows.

When a packet is input, a packet classifier of the input interface detects, based on header information of the input packet, whether the input packet is contained in a QoS-providing flow, and then which of QoS-providing flows corresponds to the QoS-providing flow.

Using the flow information detected by the packet classifier, a forwarder looks up a flow forwarding table to determine in which VOQ the input packet is to be stored. Then a VOQ controller stores the input packet in the VOQ determined by the forwarder.

A scheduler of the output interface schedules flows, which are to be output through the corresponding output port, based on QoS parameters such as Committed Information Rate (CIR) (guaranteed bandwidth) and Excess Information Rate (EIR) (allowed bandwidth), and transmits a packet forwarding command signal to the corresponding VOQ.

Upon receipt of the packet forwarding command signal from the scheduler, the VOQ controller outputs a packet so that the packet is output through the switch fabric and the corresponding output port to the outside of the system.

FIG. 2 is a flowchart of a conventional flow setting method of providing a QoS service.

Referring to FIG. 2, a QoS controller receives a QoS setting request for a packet flow, in operation S200. In operation S210, a VOQ controller determines whether there are VOQs that are not allocated a packet flow.

If there are no VOQs that are not allocated a packet flow (in operation S210), the flow setting method proceeds to operation S270. In operation S270, because no more QoS-providing flows can be set, the QoS controller reports that setting of a new flow has failed.

On the other hand, if there are VOQs that are not allocated a packet flow (in operation S210), the method proceeds to operation S220. In operation S220, the VOQ controller selects one of the VOQs that are not allocated a packet flow.

In operation S230, a scheduler sets QoS parameters for a flow from the selected VOQ. In operation 240, a forwarder adds an item for a new flow in a flow forwarding table and maps a VOQ number selected by the VOQ controller.

In operation 250, the QoS controller reports that a QoS setting for a new packet flow has succeeded. In operation 260, switching is performed for a packet contained in the new packet flow.

As a result, a QoS for a packet flow is actually applied by the scheduler, a different VOQ must be provided for a respective packet in order to provide the QoS, and the conventional method cannot provide a QoS for packet flows greater in number than the VOQs.

With the rapid increase in the number of services, such as a multimedia service and a Virtual Private Network (VPN) service, which require a guarantee in QoS such as a packet error rate, a delay time and a bandwidth, there is a growing need for guaranteeing a QoS for a packet flow of the corresponding service in a packet switching system.

In the QoS-providing packet switching system, packets destined for the same output port are stored in different VOQs depending on the QoSs required by the flows of the packets and a scheduler must schedule the packet flows destined for the same output port differently depending on the required QoSs.

Thus, unlike general packet switching systems, the QoS-providing packet switching system additionally includes a QoS controller for managing QoS-related settings and a packet classifier for detecting which QoS flow an input packet is contained in, as illustrated in FIG. 1.

The number of packet flows supporting a QoS provided by a packet switching system is determined depending on the number of VOQs of the system, and the maximum number of packet flows supporting a QoS provided by a general packet switching system is equal to the number of VOQs of the general packet switching system.

Users want more QoS-supporting flows, but increasing the number of VOQs is limited due to cost and technology. Thus, the number of flows supporting a QoS provided by a packet switching system is limited inevitably.

However, the present invention provides a QoS service for more flows using a limited number of VOQs.

### SUMMARY OF THE INVENTION

The present invention provides a packet switching system for providing a custom QoS service for more flows using a limited number of queues.

According to an aspect of the present invention, there is provided a method of setting a QoS (Quality of Service) packet flow for providing a QoS service, the method including (a) in response to a QoS packet flow setting request, determining whether there are VOQs (Virtual Output Queues) that are not pre-allocated; (b) if there are no VOQs that are not pre-allocated, determining whether there are VOQs that have not been used for a predetermined period; and (c) if there are VOQs that have not been used for the predetermined period, selecting one of the VOQs, indicating an inactive state of a flow using the selected VOQ, and releasing QoS parameters set for the flow.

The method may further include, if there are VOQs that are not pre-allocated, (a1) selecting one of the VOQs.

The method may further include (d) setting QoS parameters for the requested QoS packet flow using the VOQ selected in the operation (a1) or (c); (e) generating an item for the requested QoS packet flow and indicating an active state of the generated item; and (f) switching a packet contained in the QoS packet flow.

According to another aspect of the present invention, there is provided a method of handling a QoS (Quality of Service) packet for providing a QoS service, the method including (a) determining whether a flow containing an input packet is in an active state; (b) if the flow is not in an active state, determining whether there are VOQs (Virtual Output Queues) that are not pre-allocated; and (c) if there are VOQs that are not pre-allocated, selecting one of the VOQs, setting QoS parameters for a flow using the selected VOQ, and indicating an active state of the flow.

The method may further include (d), if there are no VOQs that are not pre-allocated, selecting one of VOQs that have not been used for a predetermined period; and (e) indicating an inactive state of a flow using the VOQ selected in the operation (d) and releasing QoS parameters set for the flow.

The method may further include, after operation (e), setting QoS parameters for a flow using the selected VOQ and indicating an active state of the flow.

The method may further include storing the input packet in the VOQ that is used by the flow that is in an active state or by the flow that uses the VOQ selected in operation (c).

According to another aspect of the present invention, there is provided a method of setting a QoS (Quality of Service) packet flow using a packet switching system, which includes a packet classifier, a VOQ (Virtual Output Queue) controller, a forwarder, a QoS controller, a scheduler, and a switch fabric, to provide a QoS service, the method including (a) in response to a QoS packet flow setting request accepted in the QoS controller, the VOQ controller determining whether there are VOQs that are not pre-allocated; (b) if there are no VOQs that are not pre-allocated, the VOQ controller determining whether there are VOQs that have not been used for a predetermined period; (c) if there are VOQs that have not been used for the predetermined period, the VOQ controller selecting one of the VOQs; (d) the forwarder indicating an inactive state of a flow using the selected VOQ in a prestored flow forwarding table; and (e) the scheduler releasing QoS parameters set for the flow using the selected VOQ.

The method may further include, if there are VOQs that are not pre-allocated, (a1) the VOQ controller selecting one of the VOQs.

The method may further include (f) the scheduler setting QoS parameters for the requested QoS packet flow using the VOQ selected in the operation (a1) or (c); (g) the forwarder generating an item for the requested QoS packet flow in the prestored flow forwarding table and indicating information about the selected VOQ and an active state of the generated item; and (h) the switch fabric switching a packet contained in the QoS packet flow.

According to another aspect of the present invention, there is provided a method of handling a QoS (Quality of Service) packet using a packet switching system, which includes a packet classifier, a VOQ (Virtual Output Queue) controller, a forwarder, a QoS controller, a scheduler, and a switch fabric, to provide a QoS service, the method including (a) the packet classifier detecting a flow containing an input packet from header information of the input packet and reporting the detected flow to the forwarder; (b) the forwarder determining whether the reported flow is in an active state in a prestored flow forwarding table; (c) if the reported flow is not in an active state, the VOQ controller determining whether there are VOQs that are not pre-allocated; (d) if there are VOQs that are not pre-allocated, the VOQ controller selecting one of the VOQs; (e) the scheduler setting QoS parameters for a flow using the selected VOQ; and (f) the forwarder indicating information about the selected VOQ and an active state of the flow in the prestored flow forwarding table.

The method may further include (g) if there are no VOQs that are not pre-allocated, the VOQ controller selecting one of VOQs that have not been used for a predetermined period; (h) the forwarder indicating an inactive state of a flow using the VOQ selected in operation (g); and (i) the scheduler releasing QoS parameters set for the flow.

The method may further include, after operation (i), the scheduler setting QoS parameters for a flow using the selected VOQ; and the forwarder indicating information about the selected VOQ and an active state of the flow in the prestored flow forwarding table.

The method may further include the forwarder searching information about the VOQ that is used by the flow that is in an active state in the prestored flow forwarding table or by the flow that uses the VOQ selected in operation (d), and reporting the searched information to the VOQ controller; and the VOQ controller storing the input packet in the VOQ corresponding to the information of the forwarder.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional packet switching system for providing a QoS (Quality of Service) service;

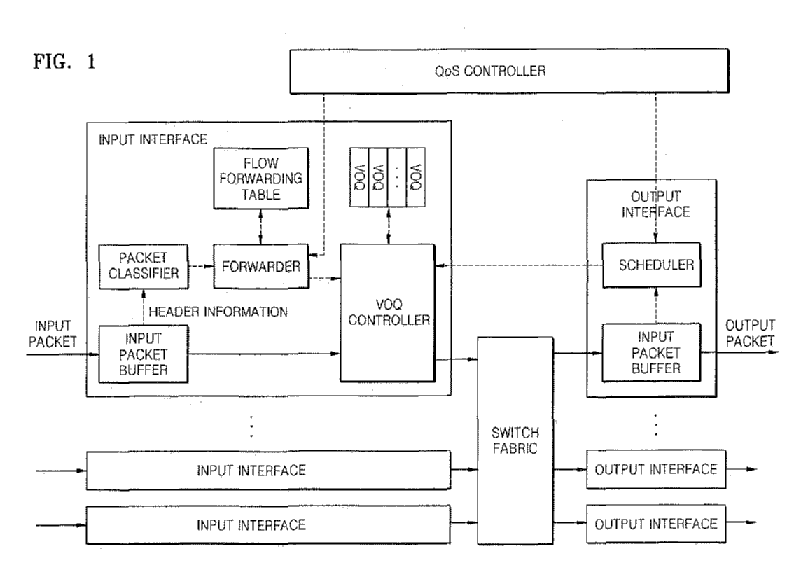

FIG. 2 is a flowchart of a conventional flow setting method of providing a QoS service;

FIG. 3 is a flowchart of a flow setting method of providing a QoS service in a packet switching systems according to an embodiment of the present invention;

FIG. 4 is a flowchart of a packet handling method of providing a QoS service in a packet switching system, according to another embodiment of the present invention;

FIG. 5 is a flowchart of a flow setting method of providing a QoS service, according to another embodiment of the present invention; and

FIG. 6 is a flowchart of a packet handling method of providing a custom QoS service, according to another embodiment of the present invention.

### DETAILED DESCRIPTION OF THE INVENTION

The present invention will now be described more fully with reference to the accompanying drawings, in which exemplary embodiments of the invention are shown.

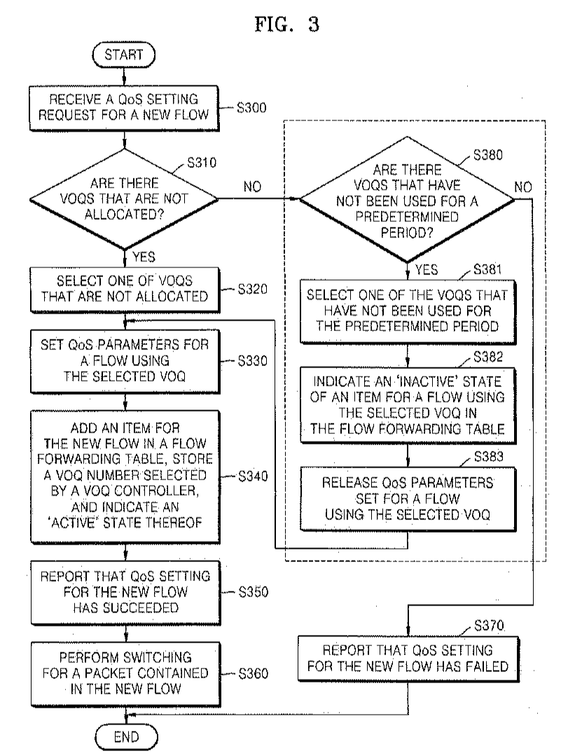

FIG. 3 is a flowchart of a flow setting method of providing a QoS (Quality of Service) service in a packet switching system, according to an embodiment of the present invention.

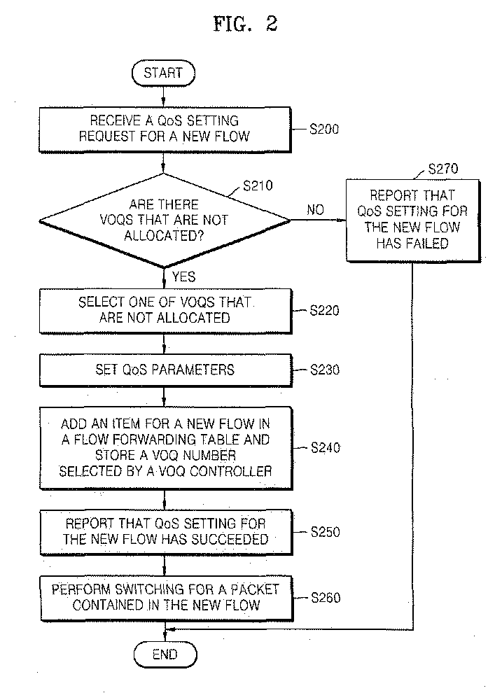

Referring to FIG. 3, a QoS controller receives a QoS setting request for a new flow, in operation S300. In operation S310, a Virtual Output Queue (VOQ) controller determines whether there are VOQs that are not allocated. If there are VOQs that are not allocated, a flow setting process is performed in operations S320 through S360, respectively in the same way as in the conventional operations S220 through S260 of FIG. 2.

On the other hand, if there are no VOQs that are not allocated, the method proceeds to operation S380. In operation S380, the VOQ controller determines whether there are VOQs that have not been used for a predetermined period.

If there are no VOQs that have not been used for the predetermined period (in operation S380), the method proceeds to operation S370. In operation S370, the QoS controller reports that setting of a new flow has failed. On the other hand, if there are VOQs that have not been used for the predetermined period (in operation S380), the method proceeds to operation S381. In operation S381, one of the VOQs that have not been used for the predetermined period is selected for use by a new packet flow.

For example, the predetermined period may be determined in consideration of a suitable design point on a system operation, depending on the state of a packet switching system, from a VOQ search point according to a QoS packet flow setting request.

In operation S382, a forwarder indicates an ‘inactive’ state of an item for a flow using the corresponding VOQ in a flow forwarding table. In operation S383, a scheduler releases QoS parameters set for a flow using the corresponding VOQ.

Thereafter, a requested QoS packet flow is set using the selected VOQ, in the same way as in the conventional QoS flow setting method.

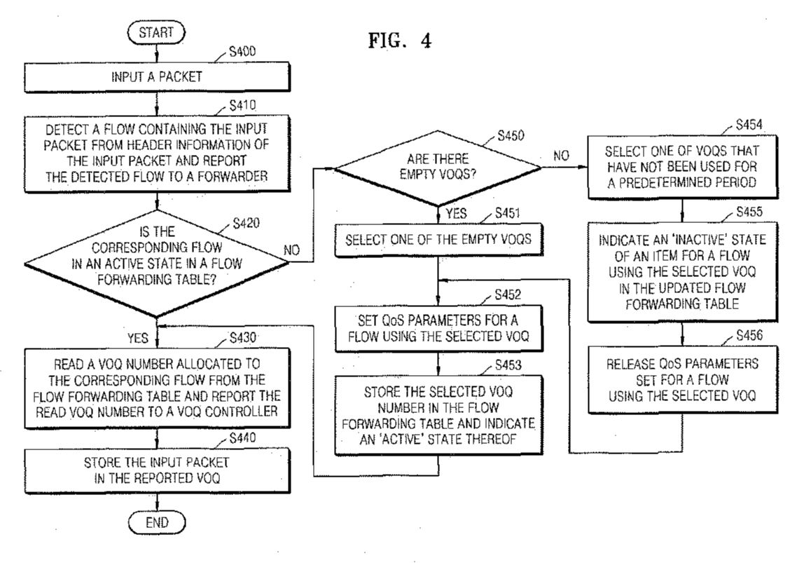

FIG. 4 is a flowchart of a packet handling method of providing a QoS service in a packet switching system, according to another embodiment of the present invention.

Referring to FIG. 4, a packet is input from the outside, in operation S400. In operation S410, a packet classifier detects a QoS flow containing the input packet from the header information of the input packet and reports the detected QoS flow to a forwarder.

In operation 420, the forwarder determines whether a corresponding QoS flow defined in a flow forwarding table is in an active state. If the corresponding QoS flow is in an active state (in operation S420), the packet processing method proceeds to operation S430. In operation S430, the forwarder reads a VOQ number allocated to the corresponding QoS flow from the flow forwarding table and reports the read VOQ number to a VOQ controller. In operation S440, the VOQ controller stores the input packet in the reported VOQ.

The subsequent processes are the same as in those in a conventional packet switching system supporting a general QoS service

When the forwarder determines the flow forwarding table, if a QoS flow containing the input packet is in an inactive state, a new VOQ must be allocated because the case is that an originally allocated VOQ is reallocated to another QoS flow.

On the other hand, if the defined flow is not in an active state (in operation S420), the method proceeds to operation S450. In operation S450, the VOQ controller determines whether there are empty VOQs. If there are empty VOQs (in operation S450), the method proceeds to operation S451. In operation S451, the VOQ controller selects one of the empty VOQs to set a scheduler. In operation S452, the scheduler updates the flow forwarding table using a new VOQ number. In operation S453, the forwarder stores the input packet in the selected VOQ.

On the other hand, if there are no empty VOQs (in operation S450), the method proceeds to operation S454. In operation S454, the VOQ controller selects a VOQ that has not been used for the longest period from among the allocated VOQs. In operation S455, the forwarder indicates an ‘inactive’ state of an item for a flow using the selected VOQ in the updated flow forwarding table. In operation S456, the scheduler releases QoS parameters set for a scheduler using the selected VOQ. Thereafter, the input packet is stored in the selected VOQ.

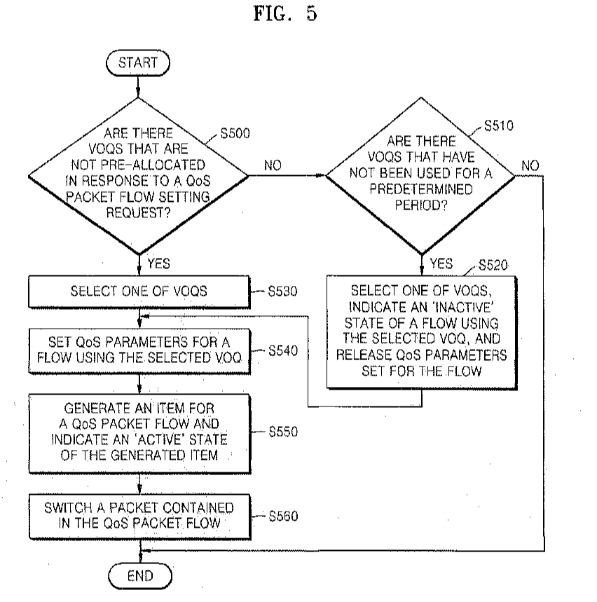

FIG. 5 is a flowchart of a flow setting method of providing a custom QoS service, according to another embodiment of the present invention.

Referring to FIG. 5, in operation S500, the packet switching system determines whether there are VOQs that are not pre-allocated in response to a QoS packet flow setting request.

If there are no VOQs that are not pre-allocated (in operation S500), the flow setting method proceeds to operation S510. In operation S510, the system determines whether there are VOQs that have not been used for a predetermined period.

If there are VOQs that have not been used for a predetermined period (in operation S510), the method proceeds to operation S520 and then to operation S540. In operation S520, the system selects one of the VOQs that have not been used for the predetermined period, indicates an ‘inactive’ state of a flow using the selected VOQ, and releases QoS parameters set for the flow.

On the other hand, if there are VOQs that are not pre-allocated (in operation S500), the method proceeds to operation S530. In operation S530, the system selects one of the VOQs that are not pre-allocated.

In operation S540, the system sets QoS parameters for a requested QoS packet flow using the VOQs selected in operation S530 or S520. In operation S550, the system generates an item for the requested QoS packet flow and indicates an ‘active’ state of the generated item.

In operation S560, the system switches the packet contained in the QoS packet flow.

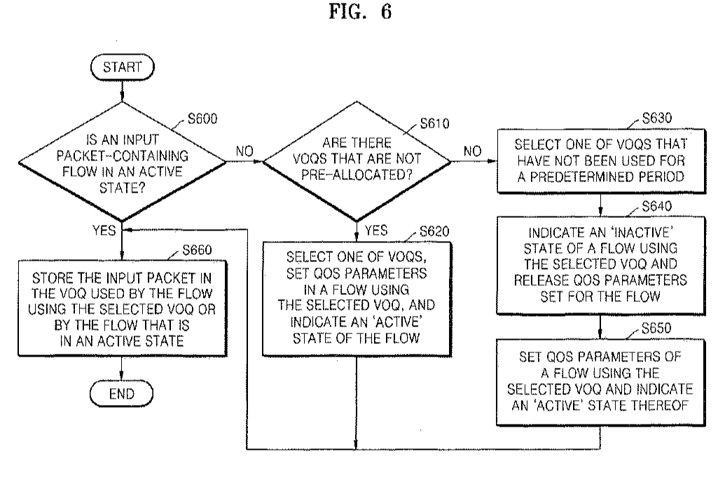

FIG. 6 is a flowchart of a packet handling method of providing a QoS service, according to another embodiment of the present invention.

Referring to FIG. 6, in operation S600, the packet switching system determines whether a flow containing an input packet is in an active state. If the flow containing an input packet is not in an active state (in operation S600), the packet processing method proceeds to operation S610. In operation S610, the system determines whether there are VOQs that are not pre-allocated.

If there are VOQs that are not pre-allocated (in operation S610), the method proceeds to operation S620. In operation S620, the system selects one of the VOQs, sets QoS parameters for a flow using the selected VOQ, and indicates an ‘active’ state of the flow.

If there are no VOQs that are not pre-allocated (in operation S610), the method proceeds to operation S630. In operation S630, the system selects one of VOQs that have not been used for a predetermined period.

In operation S640, the system indicates an ‘inactive’ sate of a flow using the selected VOQ and releases QoS parameters set for the flow.

In operation S650, the system sets QoS parameters for a flow using the selected VOQ and indicates an ‘active’ sate of the flow.

In operation S660, the system stores the input packet in the VOQ that is used by the flow that is in an ‘active’ state (in operation S600) or by the flow that uses the selected VOQ (in operation S620).

As described above, the present invention makes it possible to provide a custom QoS service for more flows using a limited number of VOQs, in a packet switching system guaranteeing a custom QoS.

Also, the present invention makes it possible to reuse a VOQ that has not been used for a predetermined period from among a limited number of VOQs. Therefore, the use time of the VOQ can be increased and thus the VOQ can be used more efficiently.

Also, the QoS packet switching system of the present invention can provide a custom QoS service for more packet flows than the conventional QoS packet switching system, and the same effects using less VOQs than the conventional QoS packet switching system, and thereby, making it possible to reduce costs.

The invention can also be embodied as computer-readable codes on a computer-readable recording medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, optical data storage devices, and carrier waves (such as data transmission through the Internet). The computer-readable recording medium can also be distributed over network-coupled computer systems so that the computer-readable code is stored and executed in a distributed fashion.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of setting a QoS (Quality of Service) packet flow for providing a QoS service, the method comprising:
(a) in response to a QoS packet flow setting request, determining whether there are VOQs (Virtual Output Queues) that are not pre-allocated;
(b) if there are no VOQs that are not pre-allocated, determining whether there are VOQs that have not been used for a predetermined period; and
(c) if there are VOQs that have not been used for the predetermined period, selecting one of the VOQs, indicating an inactive state of a flow using the selected VOQ, and releasing QoS parameters set for the flow.

2. The method of claim 1, further comprising, if there are VOQs that are not pre-allocated, (a1) selecting one of the VOQs.

3. The method of claim 2, further comprising:
(d) setting QoS parameters for the requested QoS packet flow using the VOQ selected in the operation (a1) or (c);
(e) generating an item for the requested QoS packet flow and indicating an active state of the generated item; and
(f) switching a packet contained in the QoS packet flow.

4. A method of handling a QoS (Quality of Service) packet for providing a QoS service, the method comprising:
(a) determining whether a flow containing an input packet is in an active state;
(b) if the flow is not in an active state, determining whether there are VOQs (Virtual Output Queues) that are not pre-allocated; and
(c) if there are VOQs that are not pre-allocated, selecting one of the VOQs, setting QoS parameters for a flow using the selected VOQ, and indicating an active state of the flow.

5. The method of claim 4, further comprising:
(d) if there are no VOQs that are not pre-allocated, selecting one of VOQs that have not been used for a predetermined period; and
(e) indicating an inactive state of a flow using the VOQ selected in the operation (d) and releasing QoS parameters set for the flow.

6. The method of claim 5, further comprising, after operation (e), setting QoS parameters for a flow using the selected VOQ and indicating an active state of the flow.

7. The method of claim 4, further comprising storing the input packet in the VOQ that is used by the flow that is in an active state or by the flow that uses the VOQ selected in operation (c).

8. A method of setting a QoS (Quality of Service) packet flow using a packet switching system, which includes a packet classifier, a VOQ (Virtual Output Queue) controller, a forwarder, a QoS controller, a scheduler, and a switch fabric, to provide a QoS service, the method comprising:
(a) in response to a QoS packet flow setting request accepted in the QoS controller, the VOQ controller determining whether there are VOQs that are not pre-allocated;
(b) if there are no VOQs that are not pre-allocated, the VOQ controller determining whether there are VOQs that have not been used for a predetermined period;
(c) if there are VOQs that have not been used for the predetermined period, the VOQ controller selecting one of the VOQs;
(d) the forwarder indicating an inactive state of a flow using the selected VOQ in a prestored flow forwarding table; and
(e) the scheduler releasing QoS parameters set for the flow using the selected VOQ.

9. The method of claim 8, further comprising, if there are VOQs that are not pre-allocated, (a1) the VOQ controller selecting one of the VOQs.

10. The method of claim 9, further comprising:
(f) the scheduler setting QoS parameters for the requested QoS packet flow using the VOQ selected in the operation (a1) or (c);
(g) the forwarder generating an item for the requested QoS packet flow in the prestored flow forwarding table and indicating information about the selected VOQ and an active state of the generated item; and
(h) the switch fabric switching a packet contained in the QoS packet flow.

11. A method of handling a QoS (Quality of Service) packet using a packet switching system, which includes a packet classifier, a VOQ (Virtual Output Queue) controller, a forwarder, a QoS controller, a scheduler, and a switch fabric, to provide a QoS service, the method comprising:
(a) the packet classifier detecting a flow containing an input packet from header information of the input packet and reporting the detected flow to the forwarder;
(b) the forwarder determining whether the reported flow is in an active state in a prestored flow forwarding table;
(c) if the reported flow is not in an active state, the VOQ controller determining whether there are VOQs that are not pre-allocated;
(d) if there are VOQs that are not pre-allocated, the VOQ controller selecting one of the VOQs;
(e) the scheduler setting QoS parameters for a flow using the selected VOQ; and
(f) the forwarder indicating information about the selected VOQ and an active state of the flow in the prestored flow forwarding table.

12. The method of claim 11, further comprising:
(g) if there are no VOQs that are not pre-allocated, the VOQ controller selecting one of VOQs that have not been used for a predetermined period;
(h) the forwarder indicating an inactive state of a flow using the VOQ selected in operation (g); and
(i) the scheduler releasing QoS parameters set for the flow.

13. The method of claim 12, further comprising, after operation (i):
the scheduler setting QoS parameters for a flow using the selected VOQ; and
the forwarder indicating information about the selected VOQ and an active state of the flow in the prestored flow forwarding table.

14. The method of claim 11, further comprising:
the forwarder searching information about the VOQ that is used by the flow that is in an active state in the prestored flow forwarding table or by the flow that uses the VOQ selected in operation (d), and reporting the searched information to the VOQ controller; and
the VOQ controller storing the input packet in the VOQ corresponding to the information of the forwarder.
